(19) United States
(12) Patent Application Publication
(10) Pub. No.: US 2005/0140012 A1
(43) Pub. Date: Jun. 30, 2005

(54) Method for forming copper wiring of semiconductor device

(75) Inventor: Byung-Hyun Jung, Seoul (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,927

(22) Filed: Dec. 30, 2004

(30) Foreign Application Priority Data
Dec. 31, 2003 (KR) 10-2003-0101826

(51) Int. Cl. H01L 21/4763; H01L 23/48; H01L 23/52

(52) U.S. Cl. 257/762; 257/774; 257/760; 257/750

(57) ABSTRACT

The method for forming the copper wiring of the semiconductor device includes the steps of forming a first copper wiring on a semiconductor substrate having a predetermined low structure, implanting magnesium ion on the first copper wiring, forming a magnesium oxide layer on the first copper wiring by thermal treating the first copper wiring, and forming a second copper wiring on the magnesium oxide layer.

### BACKGROUND OF THE INVENTION

(a) Field of the Invention

The present disclosures to a method for forming metal wiring and, in particular, to a method for forming the metal wiring of a semiconductor device using a dual damascene process.

(b) Description of the Related Art

Typically, the metal wiring of a semiconductor device is formed out of thin metal films such as aluminum, aluminum alloy, or copper on a semiconductor substrate so as to electrically connect the circuits formed in the semiconductor substrate. Such metal wiring, which connects the device electrodes and pads isolated by a dielectric layer such as an oxide layer, is generally formed in the order of selectively etching the dielectric layer so as to form contact holes and filling the contact holes with plugs using barrier metal and tungsten, forming a metal thin film thereon, and patterning the metal thin film so as to contact the device electrodes and pads to each other.

In order to pattern the metal wiring, typically a photolithography process is utilized. However, it becomes difficult to form fine metal wiring patterns due to the reduction of the critical dimension of the metal wiring as the semiconductor devices become miniaturized. Damascene process technology has been introduced to form fine width metal wiring to solve this problem.

Using damascene technology, a fine (narrow) width metal wiring layer may be formed by sequentially forming the tungsten plug in a contact hole of a dielectric layer, depositing an upper dielectric layer such as oxide layer on the dielectric layer, photolithographically removing a portion of the upper dielectric layer along the areas at which the metal wiring pattern is to be formed, depositing a metal thin layer on the entire surface, and planarizing the metal thin layer.

Recently, a dual damascene technique has been introduced for forming the metal wiring for contacting the lower conductive layer without forming the metal plug such as tungsten plug. In the dual damascene process, the contact holes and trenches may be formed by depositing an etch stop layer and a dielectric layer and etching the etch stop layer and the dielectric layer using the etch selectivity between the etch stop layer and the dielectric layer. Next, a barrier metal is deposited in the contact holes and trenches so as to form the metal wirings, i.e. copper wirings.

In the process for forming copper wiring, a nitride layer is used for preventing diffusion between the copper and the interlayer dielectric layer. However, the nitride layer has a drawback in that its high dielectric constant increases the overall dielectric constant of the interlayer dielectric layer.

U.S. Pat. No. 5,418,216 discloses a method for epitaxially developing a magnesium oxide layer (MgO) on a surface of a silicon thin film.

### SUMMARY OF THE INVENTION

The present invention has been made in an effort to solve the above problems, and it is an object of the present invention to provide a method for forming a copper wiring of a semiconductor device which has a spread stop layer (or diffusion barrier) of low dielectric constant and which does not further increase the RC delay.

A method for forming a copper wiring of a semiconductor device according to the present invention includes forming a first copper wiring on a semiconductor substrate having a predetermined underlying structure, implanting magnesium ions into (or otherwise depositing magnesium onto) the first copper wiring, forming a magnesium oxide-containing layer on the first copper wiring (generally by thermally treating the first copper wiring having magnesium implanted therein, or alternatively, deposited thereon), and forming a second copper wiring on the first copper wiring.

Preferably, the step of forming the first copper wiring includes depositing a first etch stop layer, an interlayer dielectric layer, a second etch stop layer, and a wiring dielectric layer on the semiconductor substrate; forming a contact hole by etching the wiring dielectric layer, the first etch stop layer, and the interlayer dielectric layer; forming a trench by etching the wiring dielectric layer; depositing a barrier metal layer and metal thin layer on inner walls of the contact hole, the trench, and the underlying structure; and removing the metal thin layer, a metal seed layer, and the barrier metal layer on the wiring dielectric layer by chemical mechanical polishing.

Preferably, the step of forming the second copper wiring includes depositing an interlayer dielectric layer, a third etch stop layer, and a wiring dielectric layer on the magnesium oxide-containing layer; forming a contact hole by etching the wiring dielectric layer, the third etch stop layer, and the interlayer dielectric layer; forming a trench by etching the wiring dielectric layer; depositing a barrier metal layer and a metal thin layer on inner walls of the contact hole, the trench, and the exposed portions of the magnesium oxide layer; and removing the metal thin layer, a metal seed layer, and the barrier metal layer on the wiring dielectric layer by chemical mechanical polishing.

Preferably, the magnesium ion is implanted in a dose range 1×10¹⁴˜1×10¹⁶ with an energy in the range of from about 10 to about 50 keV, the first copper wiring is thermally treated at a temperature in the range between 300 and 500° C., and/or the magnesium oxide-containing layer has a thickness in the range between 300 and 600 Å.

Also, the present invention concerns a semiconductor device having copper wiring thereon, comprising: a semiconductor substrate; a first etch stop layer, a first interlayer dielectric layer, and a first wiring dielectric layer on the semiconductor substrate, wherein the first etch stop layer and the first interlayer dielectric layer have a first contact hole therein, and the first wiring dielectric layer has a first trench therein; a first barrier metal layer and a first metal thin layer in the first contact hole and the first trench, in contact with an exposed surface of the substrate; a magnesium oxide-containing layer on the first metal thin layer and the first wiring dielectric layer; a second interlayer dielectric layer and a second wiring dielectric layer on the magnesium oxide-containing layer, wherein the second interlayer dielectric layer and the magnesium oxide-containing layer have a second contact hole therein, and the second wiring dielectric layer has a second trench therein; and a second barrier metal layer and a second metal thin layer in the second contact hole and the second trench, in contact with an exposed surface of the first metal thin layer. Preferably, the semiconductor device further comprises a second etch stop layer between the first interlayer dielectric layer and the first wiring dielectric layer, and a third etch stop layer between the second interlayer dielectric layer and the second wiring dielectric layer,

### BRIEF DESCRIPTION OF THE DRAWINGS

FIG. 1 to FIG. 11 are cross-sectional views illustrating fabricating steps of the semiconductor according to a preferred embodiment of the present invention.

### DETAILED DESCRIPTION OF THE PREFERRED EMBODIMENTS

With reference to the accompanying drawings, the present invention will be described in order for those skilled in the art to be able to implement the same. However, the invention is not limited to the embodiments to be described hereinafter, but, to the contrary, the invention is intended to cover various modifications and equivalent arrangements included within the sprit and scope of the appended claims.

To clarify multiple layers and regions, the thicknesses of the layers are enlarged in the drawings. Wherever possible, the same reference numbers will be used throughout the drawing(s) to refer to the same or like parts or structures. When it is said any part or structure such as a layer, film, area, or plate is positioned on another part or structure, it means the part is directly on the other part or above the other part with at least one intermediate part or structure therebetween. Any part or structure that is positioned directly on another part or structure means that there is no intermediate part or structure between them.

The method for fabricating a copper wiring of a semiconductor device according to a preferred embodiment of the present invention will be described hereinafter with reference to the accompanying drawings.

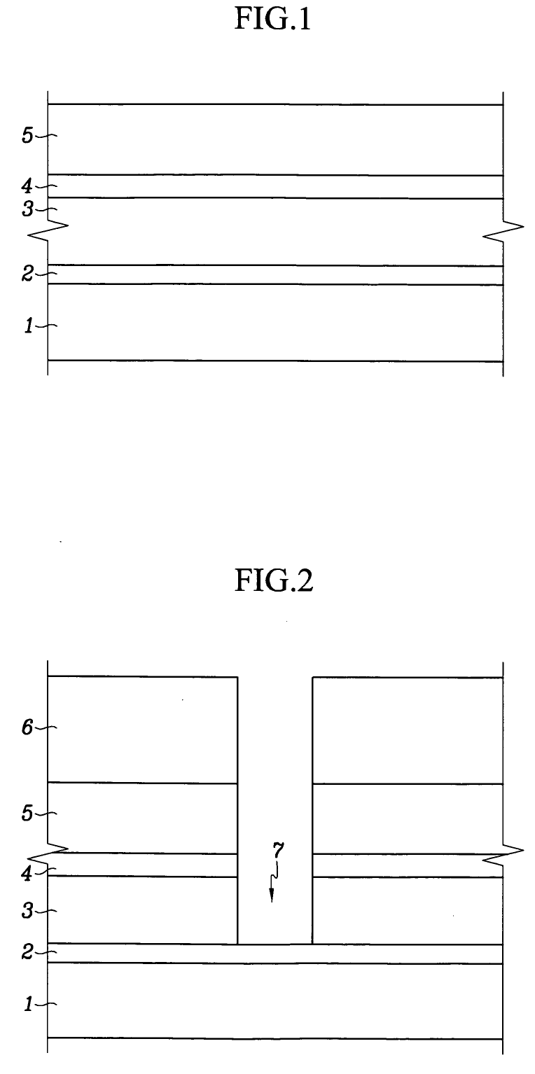

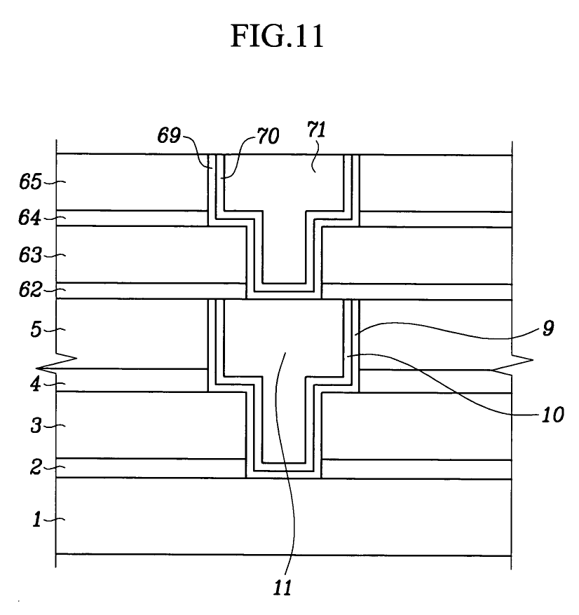

FIG. 1 to FIG. 12 are cross-sectional views illustrating fabricating steps of copper wirings of the semiconductor according to the preferred embodiment of the present invention.

As shown in FIG. 1, in the method for forming metal wiring according to a preferred embodiment of the present invention, a first etch stop layer 2 is formed for preventing device electrodes or conductive layer formed on a semiconductor device from reacting with metal wirings to be formed in subsequent processing and for using as an etch stop point while etching an interlayer dielectric layer in subsequent processing. Next, the interlayer dielectric layer 3 is deposited on the first etch stop layer 2, and then a second etch stop layer 4 is formed on the interlayer dielectric layer 3 for use as an etch stop while etching the interlayer dielectric layer in subsequent processing. Sequentially, a wiring dielectric layer 5 for forming a metal wiring layer is deposited on the second etch stop layer 4.

Preferably, the first and second etch stop layers 2 and 4 comprise a silicon nitride (SiₓN_{y}, where x is generally about 3 and y is generally about 4) layer, which may be formed using Plasma Enhanced Chemical Vapor Deposition (PECVD) equipment. Interlayer dielectric layer 3 may comprise one or more layers of dielectric material such as silicon dioxide (e.g., an undoped silicate glass [USG], silicon-rich oxide [SRO], or TEOS-based glass), a fluorosilicate glass (FSG), a borosilicate glass (BSG), a phosphosilicate glass (PSG), a borophosphosilicate glass (BPSG), etc., and be formed by conventional PECVD or high density plasma (HDP) CVD. Wiring dielectric layer 5 may comprise the same or different dielectric material(s) as interlayer dielectric layer 3 and be formed by the same or different technique(s) as interlayer dielectric layer 3. Preferably, interlayer dielectric layer 3 comprises a relatively thin layer of SRO under a relatively thick layer of FSG, and wiring dielectric layer 5 comprises SRO, which may have an underlying layer of TEOS-based glass.

As shown in FIG. 2, sequentially, a contact hole 7 is formed in the interlayer dielectric layer 3 by sequentially forming a contact hole pattern in a first photoresist layer 6 on the wiring dielectric layer 5, etching to remove the wiring dielectric layer 5 exposed through the contact hole pattern 6 as a mask using conventional plasma etching, etching again (using the same or a different plasma chemistry) to remove the exposed second etch stop layer 4, and etching again (using a plasma chemistry that selectively etches interlayer dielectric layer 3 relative to first etch stop layer 2) to remove the exposed interlayer dielectric layer 3.

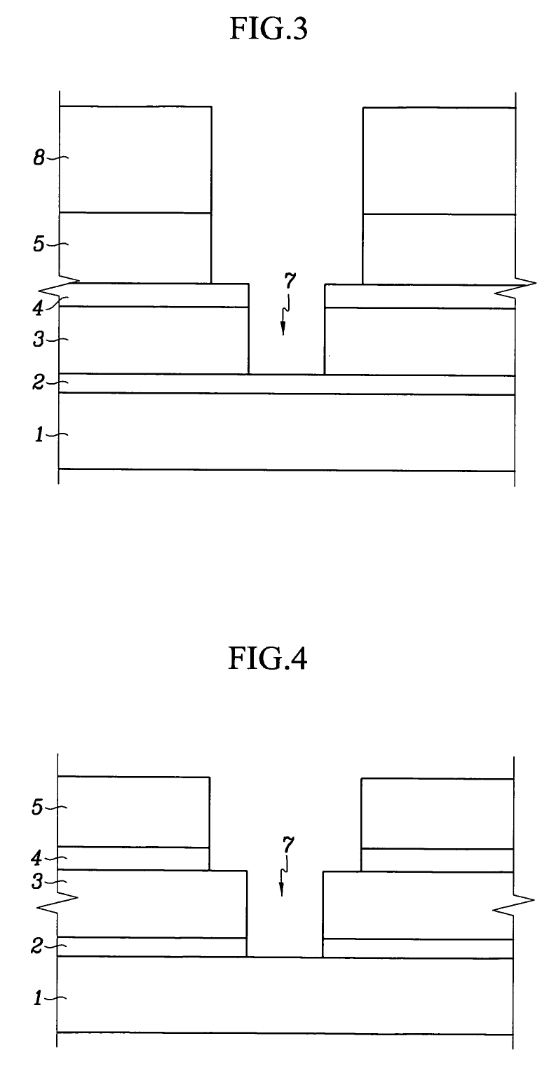

Next, as shown in FIG. 3, the contact hole photoresist 6 is removed and then a trench pattern is formed in a second photoresist layer 8 on the wiring dielectric layer 5. After forming the trench pattern, the wiring dielectric layer 5 exposed through the trench pattern in photoresist layer 8 is etched by selective plasma dry etching such that a trench is formed in wiring dielectric layer 5. Here, the second etch stop layer 4 prevents the upper surface of the interlayer dielectric layer 3 from being etched significantly by stopping the etching process (or at least significantly reducing the etch rate, e.g., by about an order of magnitude or more) on the upper surface of the interlayer dielectric layer 3. By depositing the second etch stop layer 4 on the interlayer dielectric layer 3, it is possible to prevent the interlayer dielectric layer 3 from being etched while etching the wiring dielectric layer 5.

As shown in FIG. 4, after the surface of the second etch stop layer 4 is exposed and the wiring dielectric layer 5 has been completely etched to form the trench, the photoresist layer 8 on upper surface of the wiring dielectric layer 5 is removed. The first and second etch stop layers 2 and 4, exposed respectively through the contact hole 8 of the interlayer dielectric layer 3 and the trench of the wiring dielectric layer 5, are removed by simultaneous etching. Since the first etch stop layer 2 is a dielectric layer, it must be removed to provide an electrical connection from the subsequently formed metal wiring to an exposed conductive layer in substrate 1 below the contact hole 7.

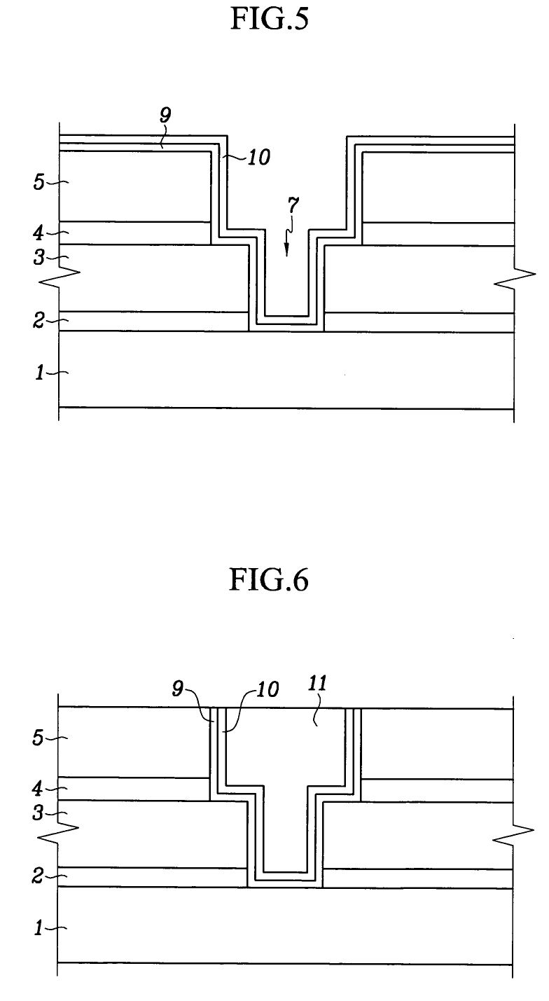

As shown in FIG. 5, sequentially, a barrier metal layer 5 is deposited on the exposed surface of the semiconductor substrate 1 (which may be a surface of a heavily-doped, thin source/drain junction, a conventional tungsten contact to such a source/drain junction or to a polysilicon or metal silicide gate layer, or an underlying conductive wiring layer, such as dual damascene copper or photolithographically-produced aluminum) for preventing the metal thin layer from reacting with the exposed conductive layer of the semiconductor substrate 1 before depositing the metal thin layer. At this time, the barrier metal layer 9 is preferably formed by depositing TaN at a thickness of several hundred A (e.g., from 100 to about 500 Å). Thereafter, a metal thin layer having superior throughput and filling characteristics is deposited generally by an electroplating process so as to fill both the contact hole 7 of the interlayer dielectric layer and the trench of the wiring dielectric layer 5. In order to grow the EPD metal thin layer, metal ions are moved towards the surface of the thin layer, and electrons are supplied to the metal ions so as to bond the metal ions to the already deposited metal. However, since the barrier metal layer 9 has high resistivity, a metal seed layer 10 (preferably comprising the same metal as the subsequently deposited metal thin layer or film) should be deposited on the barrier metal layer 9 at a thickness of several hundred A (e.g., from 100 to about 500 Å) by chemical vapor deposition (CVD) for smoothly supplying the electrons to the surface of the metal thin layer during the EPD metal thin layer deposition.

Next, as shown in FIG. 6, the contact hole 7 of the interlayer dielectric layer 3 and the trench of the wiring dielectric layer 5 are filled by depositing the metal thin layer 11 through the EPD (electroplating deposition) process. The metal thin layer 11, the metal seed layer 10, and the barrier metal layer formed on the wiring dielectric layer are polished so as to be removed from areas outside the contact hole and trench, such that the first metal wiring 11 of the semiconductor device is completely formed.

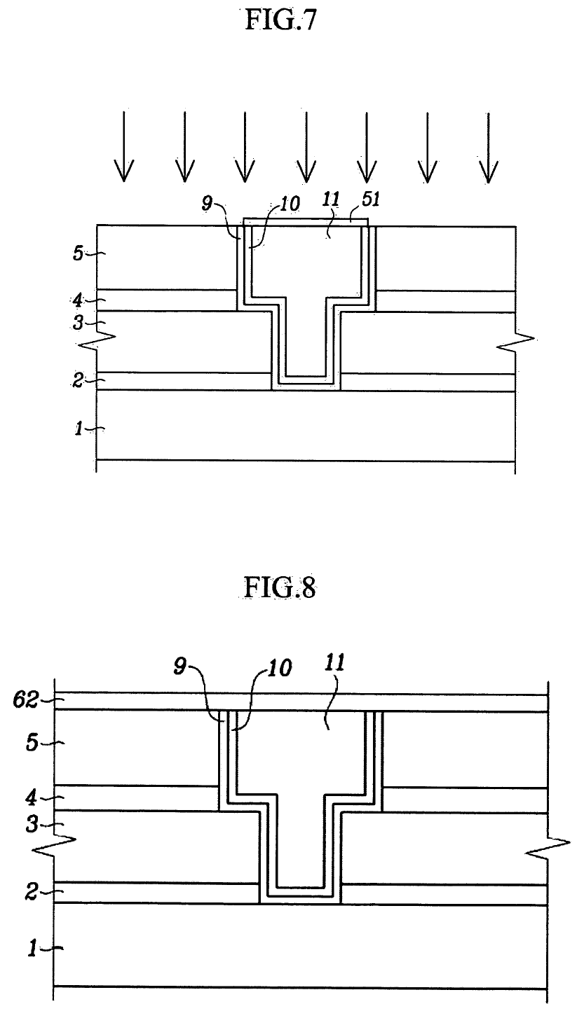

Then, as shown in FIG. 7, a copper oxide layer (CuO) 51 may be formed on the surface of the first metal wiring 11. Generally, copper oxide layer 51 may be formed by exposing copper wiring layer 11 to an oxidizing atmosphere, such as air or a controlled atmosphere containing an oxidizing agent such as dioxygen, ozone, nitric oxide, nitrous oxide, a sulfur oxide, etc., in an inert carrier gas such as nitrogen or argon, with or without heating (e.g., to a temperature of 300-400° C. or less). Thereafter, as shown in FIG. 7, magnesium (Mg) ions are injected into the first copper wiring 11. The magnesium (Mg) is implanted into the first copper wiring 11 at a dose of 1×10¹⁴ to 1×10¹⁶, a depth in the range of from 500 to about 2000 Å, and an energy of from about 10 to about 50 keV. Alternatively, a thin layer of magnesium may be deposited onto first copper wiring 11 and wiring dielectric layer 5 by sputtering or PVD.

As shown in FIG. 8, the first copper wiring 11 into which the magnesium ions are implanted is thermally treated such that a layer containing magnesium oxide (MgO; a “magnesium oxide layer”) 62 is formed on the first copper wiring 11. It is believed that the oxygen atoms from the CuO layer 51 react with the implanted (or deposited) magnesium, which is a known getterer or scavenger of oxygen, to form magnesium oxide layer 62. The magnesium oxide layer 62 acts as a spreading protection layer or diffusion barrier for preventing the copper atoms in first copper wiring 11 from spreading or diffusing to an overlying interlayer dielectric layer. The magnesium oxide-containing layer 62 preferably has a thickness of 300 to 600 Å, and is formed at a temperature in the range of 300 to 500° C.

A conventional spreading protection layer or diffusion barrier for copper wiring is formed by depositing a metal nitride layer (such as TaN) having a conductive constant of 7 to 8, which causes an RC delay problem. Also, it generally requires an additional cleaning process for removing the copper oxide 51 that may be formed on the first copper wiring 11.

However, in the present method for forming copper wiring, a copper oxide layer (CuO) 51 formed on the surface of the first copper wiring 11 is removed by heating a magnesium-containing layer, such that a separate process for removing copper oxide layer 51 is not required, and the reliability of the copper wiring may be improved. The magnesium oxide layer 62 may have a thickness in the range of from 300 to 600 Å so as to have a low conductive constant of about 6 and prevent the copper from spreading or diffusing to the upper interlayer dielectric layer 63.

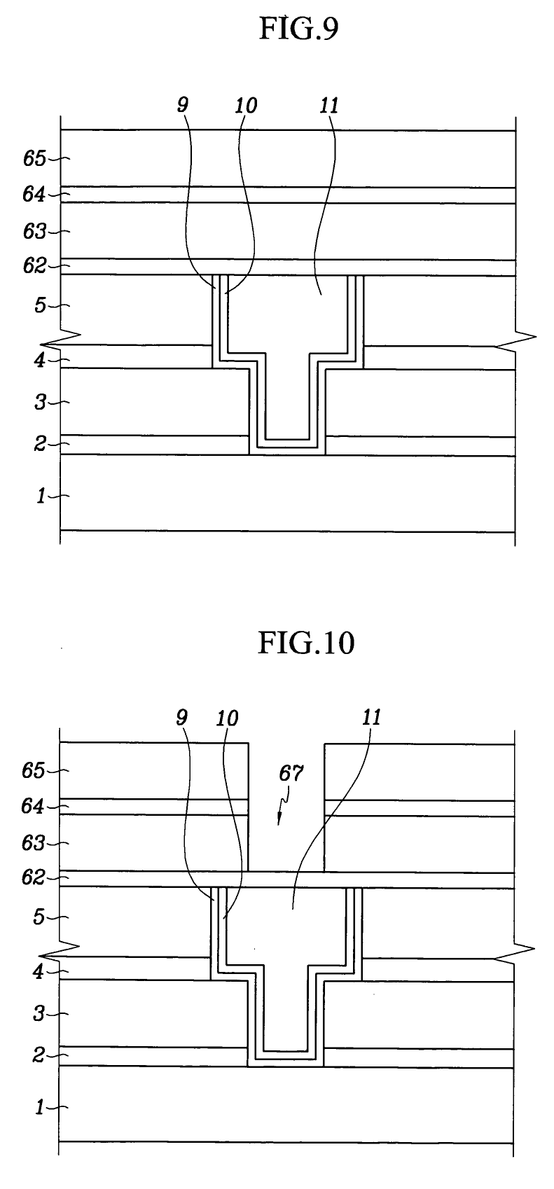

Next, as shown in FIG. 9 to FIG. 11, a second copper wiring 71 is formed on the magnesium oxide layer. A method for forming the second copper wiring 71 will be described hereinafter in more detail.

As shown in FIG. 9, an interlayer dielectric layer 63 is formed on the magnesium oxide layer 62 and wiring dielectric layer 5, a third etch stop layer 64 for use as an etch stop is formed on interlayer dielectric layer 63, and a second wiring dielectric layer 65. Interlayer dielectric layer 63 may be the same as or different from interlayer dielectric layer 3 (see, e.g., FIG. 1 and the corresponding discussion above) and may be deposited by the same process or a different process, but is preferably the same as, and is formed by the same process as, interlayer dielectric layer 3. The third etch stop layer 64 preferably comprises a silicon nitride (SiN) layer, and is preferably deposited using PECVD. Second wiring dielectric layer 65 may be the same as or different from wiring dielectric layer 5 (see, e.g., FIG. 1 and the corresponding discussion above) and may be deposited by the same process or a different process, but is preferably the same as, and is formed by the same process as, wiring dielectric layer 5.

Next, as shown in FIG. 10, a contact hole is formed in the interlayer dielectric layer 63 by sequentially forming a contact hole pattern on the wiring dielectric layer 65, etching to remove the wiring dielectric layer 65 exposed through the contact hole pattern as a mask using the plasma dry etch technique, etching again to remove the third etch stop layer 64, and etching again the exposed interlayer dielectric layer 63, similar to the process described above with regard to FIG. 2.

Next, as shown in FIG. 12, a second copper wiring 71 is formed in the same manner as for forming the first copper wiring 11. That is, after removing the contact hole pattern photoresist, a trench pattern is formed on the upper surface of the wiring dielectric layer 65. Thereafter, the wiring dielectric layer 65 exposed using the trench pattern as a mask is removed by plasma dry etching such that the trench, in which the metal wiring is to be formed, is formed in the wiring dielectric layer 65. At this time, the third etch stop layer 64 stops the etch process so as to prevent the interlayer dielectric layer 63 from being etched. In this manner, the third etch stop layer 64 prevents the interlayer dielectric layer 63 from being unnecessarily etched while the wiring dielectric layer 65 is etched.

After the third etch stop layer 64 is exposed and the wiring dielectric layer 65 has been completely etched to form the trench, the trench pattern photoresist on the upper surface of the wiring dielectric layer 65 is removed. Thereafter, the magnesium oxide layer 62 exposed through the contact hole 67 of the interlayer dielectric layer 63 and the third etch stop layer 64 are simultaneously removed by plasma etching, preferably using an etch chemistry that is substantially non-selective with regard to etching the etch stop layer 64 and magnesium oxide layer 62, but is selective for such materials with regard to underlying first copper wiring 11.

Next, a barrier metal layer 69 is deposited on the surface of the first copper wiring 11 and the trench and contact hole sidewalls. At this time, the barrier metal layer 69 may be formed by depositing TaN at a thickness of several hundreds of Angstroms (e.g., from 100 to about 500 Å). Thereafter, the contact hole 67 of the interlayer dielectric layer 63 and the trench of the wiring dielectric layer 65 are filled by the EPD metal thin layer having superior throughput and filling characteristics. Typically, in order to grow the EPD metal thin layer, metal ions are moved towards the surface of the metal thin layer, and electrons are supplied to the metal ions so as to bond the metal ions to the deposited metal. However, since the barrier metal layer 69 has high resistivity, a metal seed layer 70 should be deposited on the barrier metal layer 69 at a thickness of several hundreds of Angstroms (e.g., from 100 to about 500 Å) by chemical vapor deposition (CVD) for smoothly supplying the electrons to the surface of the thin layer during the EPD metal thin layer deposition.

Next, the contact hole 67 of the interlayer dielectric layer 63 and the trench of the wiring dielectric layer 65 are filled by the metal thin layer 71 through the EPD process. The second metal wiring 71 is completely formed by removing the metal thin layer 71, metal seed layer 70 and the barrier metal layer 69 from the upper surface of the wiring dielectric layer 65 by chemical mechanical polishing (CMP). The second metal wiring 71 preferably comprises copper.

Although preferred embodiments of the present invention have been described in detail hereinabove, it should be clearly understood that many variations and/or modifications of the basic inventive concepts herein taught which may appear to those skilled in the present art will still fall within the sprit and scope of the present invention, as defined in the appended claims.

In the method for forming copper wiring for a semiconductor device according to the present invention, a spread protection layer (e.g., diffusion barrier) for preventing the copper from spreading into the interlayer dielectric layer comprises magnesium oxide (MgO) having a low conductive constant such that an RC delay time is not significantly reduced. Also, in the present invention, a copper oxide (CuO) layer formed on the surface of the copper wiring is removed, and simultaneously, a magnesium oxide (MgO) layer is formed by sequentially implanting Mg ions into the surface of the copper wiring and thermally treating (e.g., heating) the Mg-implanted device. Thus, it is possible to improve the reliability of copper wiring using the present invention by removing the copper oxide (CuO) layer.

1. A method for forming copper wiring, comprising:
forming a first copper wiring on a semiconductor substrate;
implanting magnesium ions into the first copper wiring;
thermally treating the first copper wiring to form a layer comprising magnesium oxide on the first copper wiring; and
forming a second copper wiring on the first copper wiring.

2. The method of claim 1, wherein forming the first copper wiring comprises:
depositing a first etch stop layer, an interlayer dielectric layer, a second etch stop layer, and a wiring dielectric layer on the semiconductor substrate;
etching the wiring dielectric layer, the second etch stop layer, and the interlayer dielectric layer to form a contact hole;
etching the wiring dielectric layer to form a trench;
depositing a barrier metal layer and metal thin layer on inner walls of the contact hole and the trench, and the underlying structure; and
removing the metal thin layer and the barrier metal layer from over the wiring dielectric layer by chemical mechanical polishing.

3. The method of claim 2, further comprising, after etching the wiring dielectric layer and before depositing the barrier metal layer and metal thin layer, etching the first etch stop layer to expose a surface of the substrate.

4. The method of claim 2, further comprising depositing a metal seed layer after depositing the barrier metal layer and before depositing the metal thin layer.

5. The method of claim 1, wherein the step of forming the second copper wiring includes:
depositing a second interlayer dielectric layer, a third etch stop layer, and a second wiring dielectric layer on the magnesium oxide-containing layer;
etching the second wiring dielectric layer, the third etch stop layer, and the second interlayer dielectric layer to form a second contact hole;
etching the second wiring dielectric layer to form a second trench;
depositing a second barrier metal layer and a second metal thin layer on inner walls of the second contact hole, the second trench, and the underlying structure; and
removing the second metal thin layer and the second barrier metal layer from over the second wiring dielectric layer by chemical mechanical polishing.

6. The method of claim 5, further comprising depositing a second metal seed layer after depositing the second barrier metal layer and before depositing the second metal thin layer.

7. The method of claim 5, further comprising, after etching the second wiring dielectric layer and before depositing the second barrier metal layer and second metal thin layer, etching the magnesium oxide-containing layer to expose a surface of the first copper wiring.

8. The method of claim 1, wherein the magnesium ions are implanted in a dose range of from about 1×10¹⁴ to about 1×10¹⁶.

9. The method of claim 1, wherein the magnesium ions are implanted with an energy in the range of from 10 to about 50 keV.

10. The method of claim 1, wherein said thermally treating comprises heating the first copper wiring at a temperature in the range of from about 300 to 500° C.

11. The method of claim 1, wherein the magnesium oxide-containing layer has a thickness in the range of from about 300 to about 600 Å.

12. A method for forming copper wiring, comprising:
forming a first copper wiring on a semiconductor substrate;
forming a magnesium-containing layer on the first copper wiring;
thermally treating the first copper wiring and the magnesium-containing layer to form a layer comprising magnesium oxide on the first copper wiring; and
forming a second copper wiring on the first copper wiring.

13. The method of claim 12, wherein forming the first copper wiring comprises:
depositing a first etch stop layer, a first interlayer dielectric layer, a second etch stop layer, and a first wiring dielectric layer on the semiconductor substrate;
etching the first wiring dielectric layer, the second etch stop layer, and the first interlayer dielectric layer to form a first contact hole;
etching the first wiring dielectric layer to form a first trench;
etching the first etch stop layer to expose a surface of the substrate;
depositing a first barrier metal layer, a first metal seed layer, and a first metal thin layer on inner walls of the first contact hole and the first trench, and on the exposed surface of the substrate; and
removing the first metal thin layer and the first barrier metal layer from over the first wiring dielectric layer by chemical mechanical polishing.

14. The method of claim 12, wherein the step of forming the second copper wiring includes:
depositing a second interlayer dielectric layer, a third etch stop layer, and a second wiring dielectric layer on the magnesium oxide-containing layer;
etching the second wiring dielectric layer, the third etch stop layer, and the second interlayer dielectric layer to form a second contact hole;
etching the second wiring dielectric layer to form a second trench;
etching the magnesium oxide-containing layer to expose a surface of the first copper wiring;
depositing a second barrier metal layer, a second metal seed layer, and a second metal thin layer on inner walls of the second contact hole, the second trench, and the exposed surface of the first copper wiring; and
removing the second metal thin layer and the second barrier metal layer from over the second wiring dielectric layer by chemical mechanical polishing.

15. The method of claim 12, wherein the magnesium ions are implanted in a dose range of from about 1×10¹⁴ to about 1×10¹⁶.

16. The method of claim 12, wherein the magnesium ions are implanted with an energy in the range of from 10 to about 50 keV.

17. The method of claim 12, wherein said thermally treating comprises heating the first copper wiring at a temperature in the range of from about 300 to 500° C.

18. The method of claim 12, wherein the magnesium oxide-containing layer has a thickness in the range of from about 300 to about 600 Å.

19. A semiconductor device having copper wiring thereon, comprising:
a semiconductor substrate;
a first etch stop layer, a first interlayer dielectric layer, and a first wiring dielectric layer on the semiconductor substrate, wherein the first etch stop layer and the first interlayer dielectric layer have a first contact hole therein, and the first wiring dielectric layer has a first trench therein;
a first barrier metal layer and a first metal thin layer in the first contact hole and the first trench, in contact with an exposed surface of the substrate;
a magnesium oxide-containing layer on the first metal thin layer and the first wiring dielectric layer;
a second interlayer dielectric layer and a second wiring dielectric layer on the magnesium oxide-containing layer, wherein the second interlayer dielectric layer and the magnesium oxide-containing layer have a second contact hole therein, and the second wiring dielectric layer has a second trench therein;
a second barrier metal layer and a second metal thin layer in the second contact hole and the second trench, in contact with an exposed surface of the first metal thin layer.

20. The semiconductor device of claim 19, further comprising a second etch stop layer between the first interlayer dielectric layer and the first wiring dielectric layer, and a third etch stop layer between the second interlayer dielectric layer and the second wiring dielectric layer,

21. The semiconductor device of claim 19, wherein the first and second metal thin layers each comprise copper.

22. The semiconductor device of claim 19, further comprising a first metal seed layer between the first barrier metal layer and the first metal thin layer and a second metal seed layer between the second barrier metal layer and the second metal thin layer.

23. The semiconductor device of claim 22, wherein the first and second metal thin layers and the first and second metal seed layers each comprise copper.
